(19) United States
(12) Patent Application Publication
(10) Pub. No.: US 2024/0413171 A1
(43) Pub. Date: Dec. 12, 2024

(54) ELECTRONIC DEVICE

(71) Applicant: PanelSemi Corporation, New Taipei City (TW)

(72) Inventor: Sheng-Ping CHIANG, New Taipei City (TW)

(21) Appl. No.: 18/737,198

(22) Filed: Jun. 7, 2024

Related U.S. Application Data
(60) Provisional application No. 63/506,972, filed on Jun. 8, 2023.

(51) Int. Cl. H01L 27/12; H01L 23/498

(52) U.S. Cl. CPC H01L 27/124; H01L 23/4985

(57) ABSTRACT

An electronic device includes a flexible substrate, a conductive pattern layer, at least one transistor and at least one guarding portion. The transistor electrically connects the conductive pattern layer. The transistor includes an active layer, a source electrode and a drain electrode electrically connected to the active layer, at least one gate electrode, and an insulation layer disposed between the active layer and the gate electrode. The active layer defines a channel portion, which defines a gated channel overlapped with the gate electrode in a projection direction perpendicular to the flexible substrate. The gated channel defines a plurality of edges coherent to the first direction. The guarding portion is arranged under the transistor and overlaps at least one of the edges of the gated channel in the projection direction perpendicular to the flexible substrate. The Young's modulus of the flexible substrate is less than that of the guarding portion.

### CROSS REFERENCE TO RELATED APPLICATIONS

This Non-provisional application which claims priority under 35 U.S.C. § 119(a) on Patent Application Nos. 63/506,972 filed in United States of America on Jun. 8, 2023, the entire contents of which are hereby incorporated by reference.

### BACKGROUND

### Technology Field

The disclosure relates to an electronic device and specifically refer to an electronic device with transistors.

### Description of Related Art

A transistor is one kind of semiconductor element which is capable to amplify or switch electronic signals. The transistor can be used in an audio, a radio, and a television as an amplifier for amplifying weak signals, or used in a computer, a smartphone, and any of other electronic devices as a switch for controlling the flow of electrical current. In addition, the transistor can form a logic gate to perform Boolean logic operations in which the logic gate is the basis of computers and microprocessors. Further, the transistor can be used as a power regulator to control the output of voltage and current by an electronic equipment for stable operation. Therefore, the transistor is widely used in different electronic devices.

However, the transistor used in a flexible electronic device is challenged, especially when the flexible electronic device is repeatedly bent or rolled. The transistor will be damaged and lead to current leakage, thereby affecting the functionality of flexible electronic devices.

### SUMMARY

One or more exemplary embodiments of this disclosure are to provide an electronic device.

This disclosure is to provide an electronic device, which includes a flexible substrate, a conductive pattern layer, at least one transistor, and at least one guarding portion.

The conductive pattern layer and the at least one transistor are formed on the flexible substrate.

The at least one transistor electrically connects the conductive pattern. The least one transistors includes an active layer, a source electrode and a drain electrode respectively electrically connected to the active layer, at least one gate electrode, and an insulation layer disposed between the active layer and the gate electrode. The active layer of the at least one transistor defines a channel portion, and the channel portion defines a gated channel. The gated channel is overlapped with the gate electrode in a projection direction perpendicular to the flexible substrate. The channel portion further defines a first direction parallel to a direction of a current flowing between the drain electrode and the source electrode, and the gated channel defines a plurality of edges coherent to the first direction at a peripheral thereof.

The at least one guarding portion is arranged under the at least one transistor, and the at least one guarding portion overlaps at least one of the edges of the gated channel in the projection direction perpendicular to the flexible substrate. The Young's modulus of the flexible substrate is less than the Young's modulus of the guarding portion.

In one case, the at least one guarding portion is electrically insulated from the conductive pattern layer.

In one case, the at least one guarding portion is electrically insulated from the at least one transistor.

In one case, the at least one guarding portion is electrically insulated from the gate electrode of the at least one transistor.

In one case, the at least one guarding portion is disposed on the flexible substrate.

In one case, the at least one guarding portion is arranged under the flexible substrate.

In one case, the at least one guarding portion is integrated with the flexible substrate.

In one case, the electronic device further includes a support board stacked under the flexible substrate, and the Young's modulus of the support board is less than the Young's modulus of the at least one guarding portion.

In one case, the at least one guarding portion is disposed either on the flexible substrate or on the support board.

In one case, the at least one guarding portion is integrated with the support board.

In one case, the at least one transistor is a thin film transistor.

In one case, the at least one transistor comprises a single-gate transistor or a multi-gate transistor.

In one case, the multi-gate transistor comprises a double-gate transistor, or a triple-gate transistor.

In one case, the at least one transistor is a top-gate transistor or a bottom-gate transistor.

In one case, the channel portion of the at least one transistor further defines a second direction perpendicular to the first direction, and the channel portion defines a width along the second direction in which the width is a fixed-width.

In one case, an outermost contour of the at least one guarding portion is square, polygon, circle, or ellipse.

In one case, the at least one guarding portion is a porous structure, a honeycomb-like structure, a mesh, or a grille-like structure.

In one case, the at least one guarding portion fully overlaps the gated channel of the channel portion in the projection direction perpendicular to the flexible substrate.

In one case, the electronic device comprises a plurality of transistors and a plurality of guarding portions, and the at least one of the plural guarding portions overlaps with the gated channels of at least two of the transistors in the projection direction perpendicular to the flexible substrate.

In one case, the insulation layer of the at least one transistor is a dielectric layer.

In one case, the electronic device further includes a plurality of lighting members individually from each other and disposed directly on the flexible substrate, and the lighting members are electrically connected to the conductive pattern layer.

In one case, one or ones of the lighting members are driven by the at least one transistor.

Accordingly, the transistor(s) of this disclosure can maintain its function when the electronic device is bent or rolled since a stress will not accumulate at the edges of the channel portion(s) of the transistor(s).

### BRIEF DESCRIPTION OF THE DRAWINGS

FIG. 1(A) to FIG. 1(E) are diagrams showing different arrangements of the guarding portions in embodiments of this disclosure;

FIG. 2(A) to FIG. 2(D) are diagrams showing arrangements of the guarding portions in embodiments with support boards of this disclosure;

FIG. 3 is an exploded diagram showing relations of a gate electrode and a channel portion of a transistor to a corresponding guarding portion of this disclosure;

FIG. 4(A) and FIG. 4(B) are diagrams showing different types of the guarding portions in one embodiments of this disclosure; and

FIG. 5(A) to FIG. 5(C) are schematic diagrams showing stress accumulation when the electronic device of this disclosure is bent or rolled.

### DETAILED DESCRIPTION OF THE DISCLOSURE

The disclosure will become more fully understood from the detailed description and accompanying drawings, which are given for illustration only, and thus are not limitative of the present disclosure.

The present disclosure will be apparent from the following detailed description, which proceeds with reference to the accompanying drawings, wherein the same references relate to the same elements.

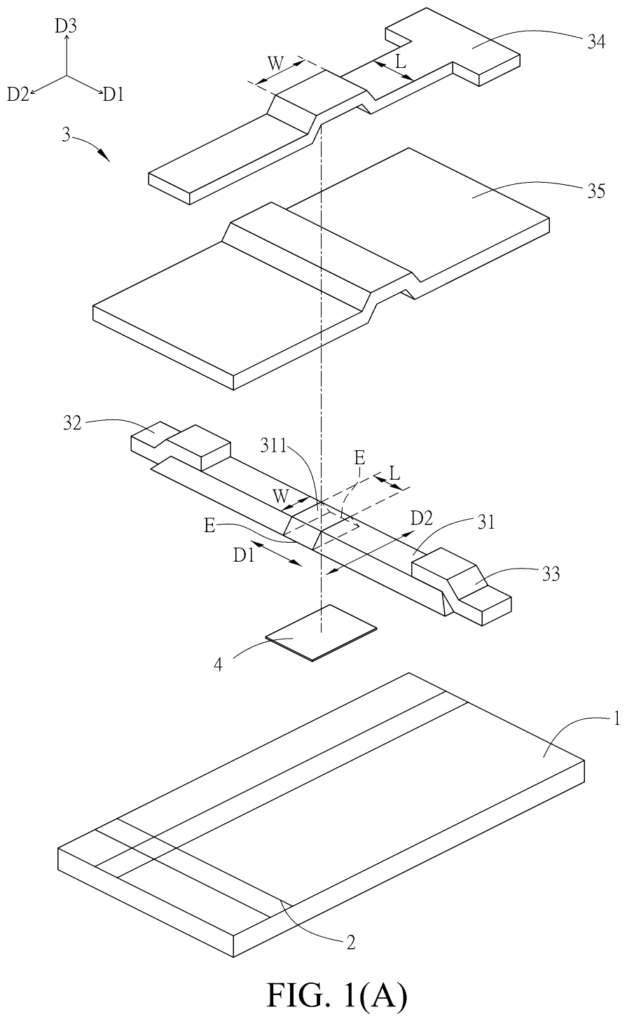

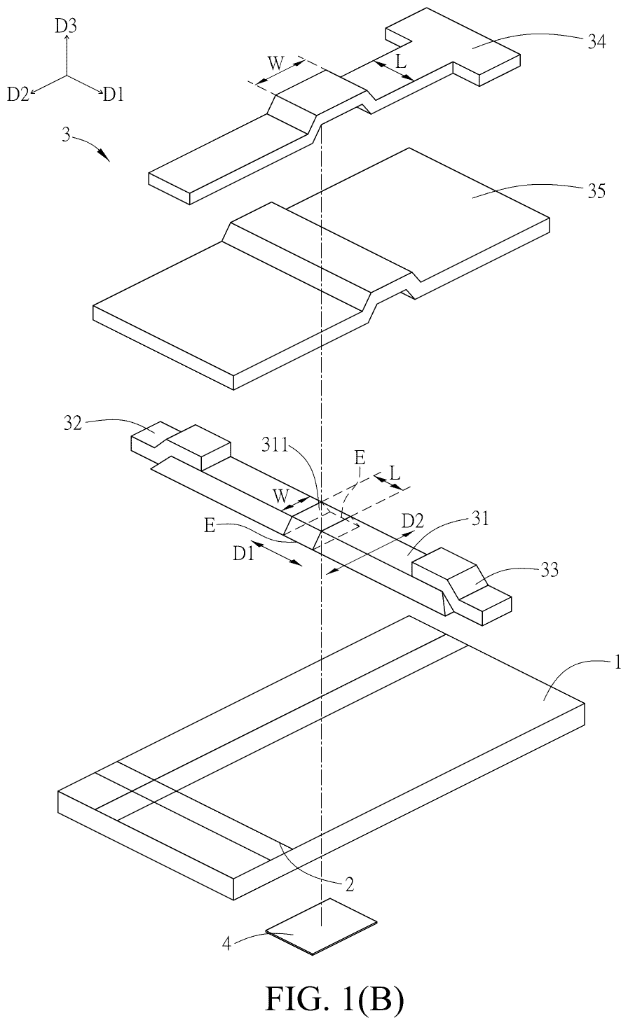

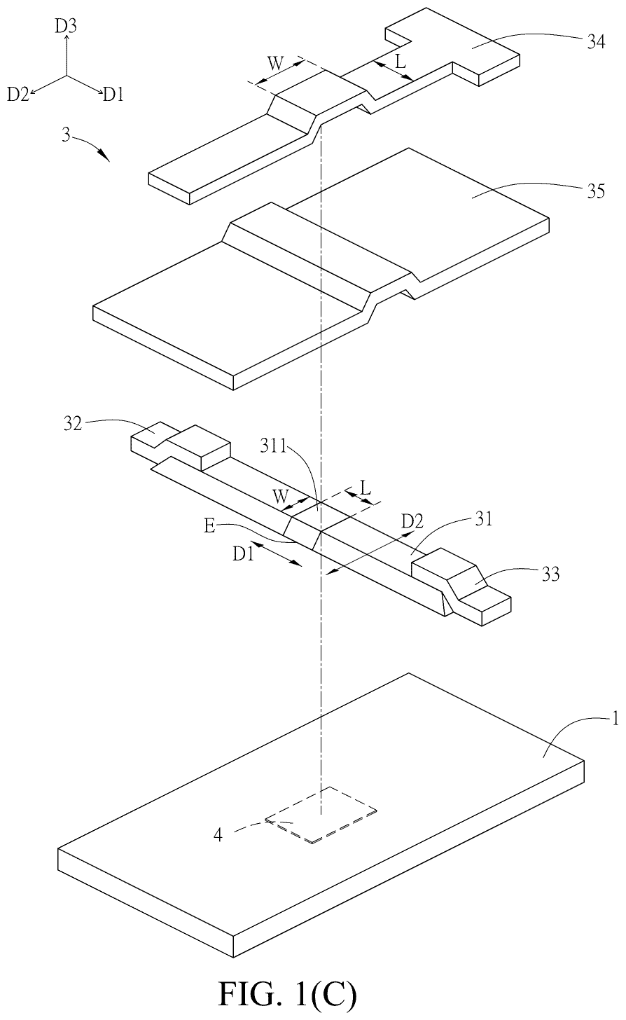

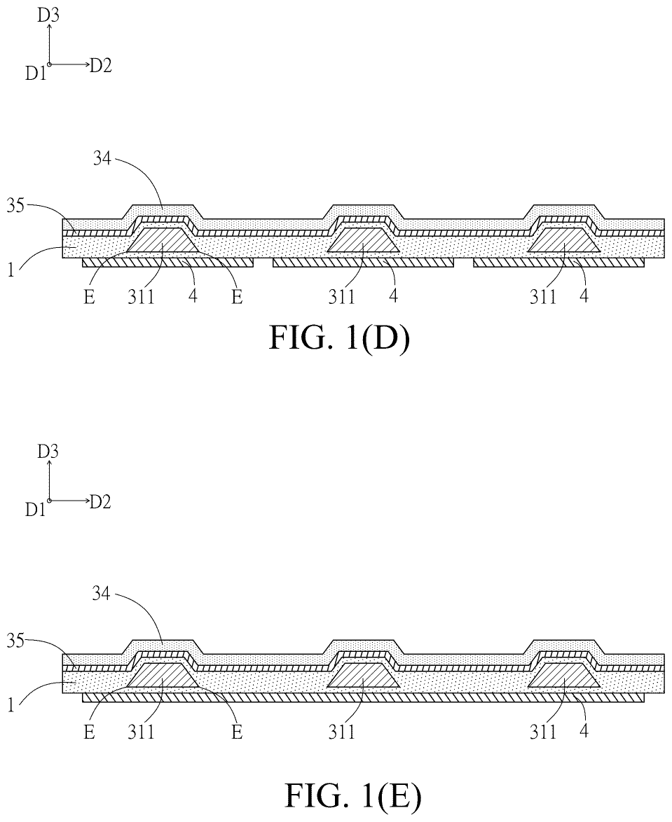

FIG. 1(A) to FIG. 1(C) are three exploded diagrams showing different embodiments of the present disclosure. The electric device of the present disclosure comprises a flexible substrate 1, a conductive pattern layer 2 formed on the flexible substrate 1, at least one transistor 3 arranged on the flexible substrate 1, and at least one guarding portion 4 arranged under the transistor 3, such as being arranged between the transistors 3 and the flexible substrate 1 as shown in FIG. 1(A) or arranged beneath the flexible substrate 1 as shown in FIG. 1(B). The guarding portion 4 can be arranged on a top surface of the flexible substrate 1 in FIG. 1(A), or the guarding portion 4 can be arranged on a bottom surface of the flexible substrate 1 in FIG. 1(B). In addition, the guarding portion 4 can be integrated with the flexible substrate 1 as shown in FIG. 1(C). Further, the Young's modulus of the flexible substrate 1 is less than the Young's modulus of at least one guarding portion 4. The materials of the flexible substrate 1 is not limited.

The guarding portion 4 could be made of conductive material, insulating material or dielectronic materials. However, the guarding portion 4 is isolated from the transistor 3 by insulation design or a fixed potential such as grounding, capacitor coupling, and high-impedance component solutions. The guarding portions 4 could be of insulation, dielectronic or metallic materials, and they are also arranged to be electrically connected to or insulated from the conductive pattern layer 2.

In addition, the shape, the configuration or the outermost contour of the guarding portion 4 is not limited. The outermost contour of the guarding portion 4 can be a square, a polygon, a circle, or an ellipse, but not limited thereto.

The transistor 3 is electrically connected to the conductive pattern layer 2. The transistor 3 includes an active layer defining a channel portion 31, a source electrode 32, a drain electrode 33, a gate electrode 34, and a dielectric layer 35 disposed between the channel portion 31 and the gate electrode 34. The source electrode 32 and the drain electrode 33 are electrically connected to the active layer of the transistor, especially to the channel portion 31. The channel portion 31 further defines a gated channel 311, and at least partial of the channel portion 31 overlaps with the gate electrode 34 in a projection direction D3 perpendicular to the flexible substrate 1.

The channel portion 31 further defines a first direction D1 and a second direction D2 along a surface of the flexible substrate 1. The first direction D1 is parallel to a direction of a current flowing between the source electrode 32 and the drain electrode 33. In other words, the first direction D1 extends between the source electrode 32 and the drain electrode 33. The second direction D2 is perpendicular to the first direction D1. The gated channel 311 of the channel portion 31 further defines a plurality of edges E coherent to the first direction D1 at a peripheral thereof.

To be noted, the guarding portion 4 overlaps at least one of the edges E of the gated channel 311 in a projection direction D3 perpendicular to the flexible substrate 1. The guarding portion 4 can be a non-porous structure, a porous structure, a honeycomb-like structure, a mesh, or a grille-like structure, but not limited thereto. In some cases, the gated channel 311 of the channel portion 31 is fully overlaps with the guarding portion 4 in the projection direction D3 perpendicular to the flexible substrate 1.

In FIG. 1(D), the transistors 3 and the guarding portions 4 are arranged in one-on-one manner, and the gated channel 311 of the transistor 3 is overlaps with the corresponding guarding portion 4 in the projection direction D3 perpendicular to the flexible substrate 1.

In another case, the arrangement of the transistors 3 and the guarding portions 4 is plural-on-one manner, ex. three-on-one manner in FIG. 1(E). The gated channels 311 of these three transistors 3 are overlaps with one guarding portion 4 in the projection direction D3 perpendicular to the flexible substrate 1.

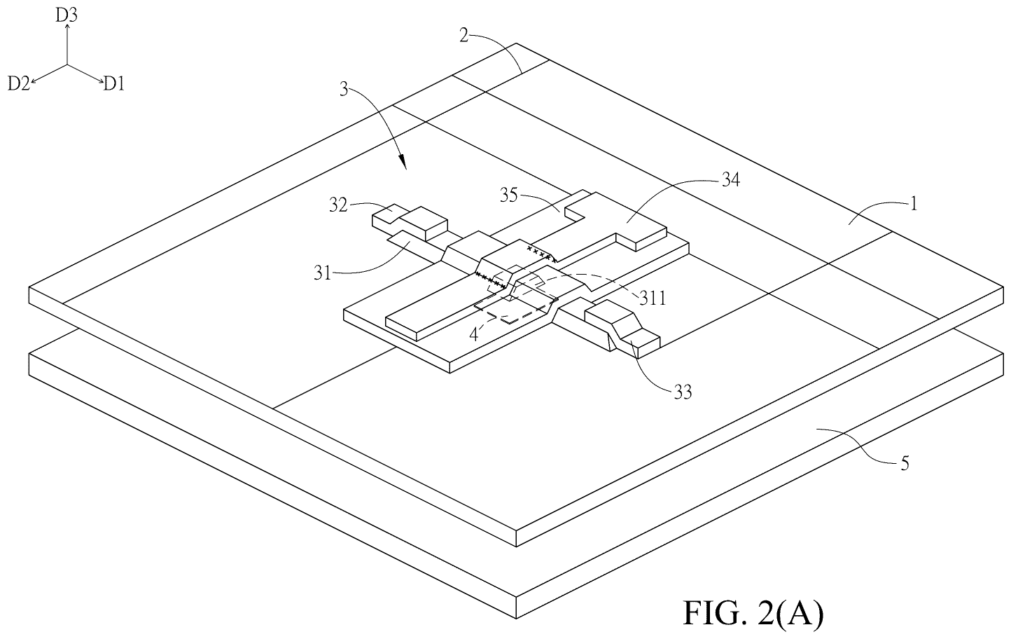

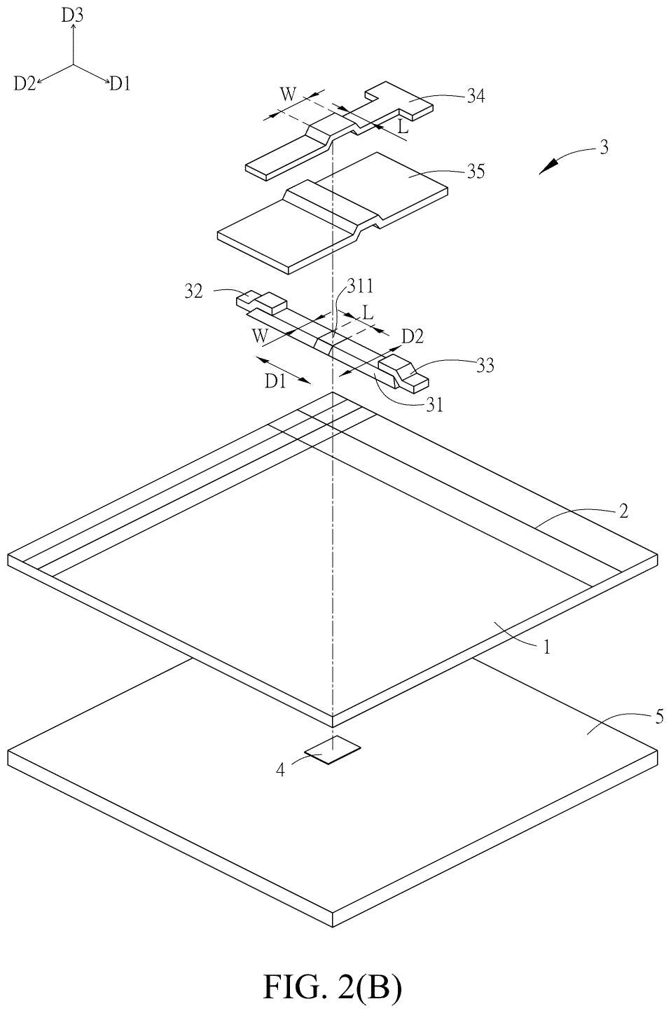

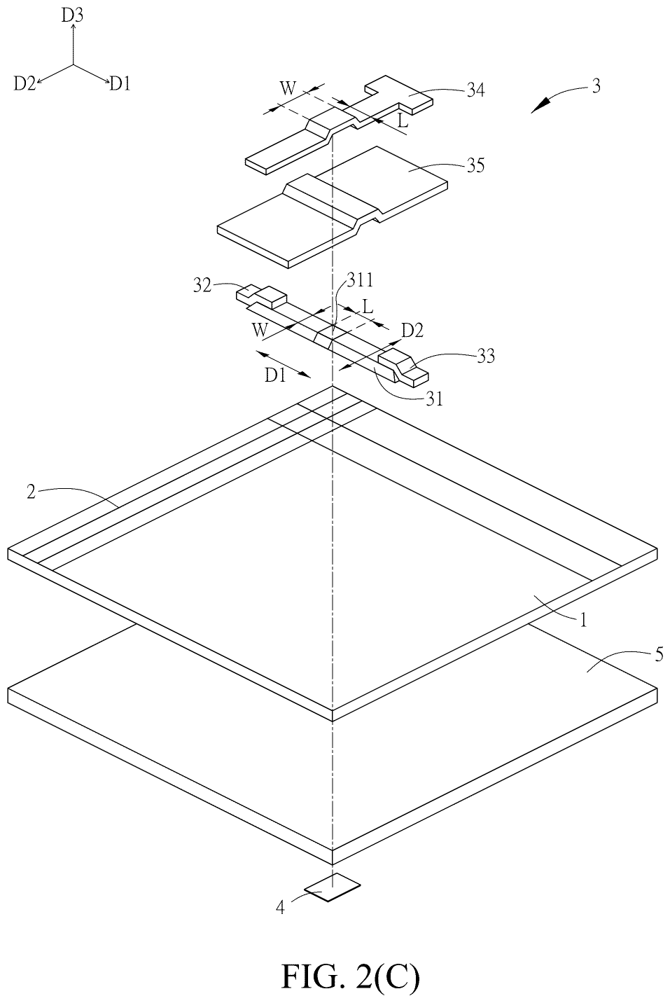

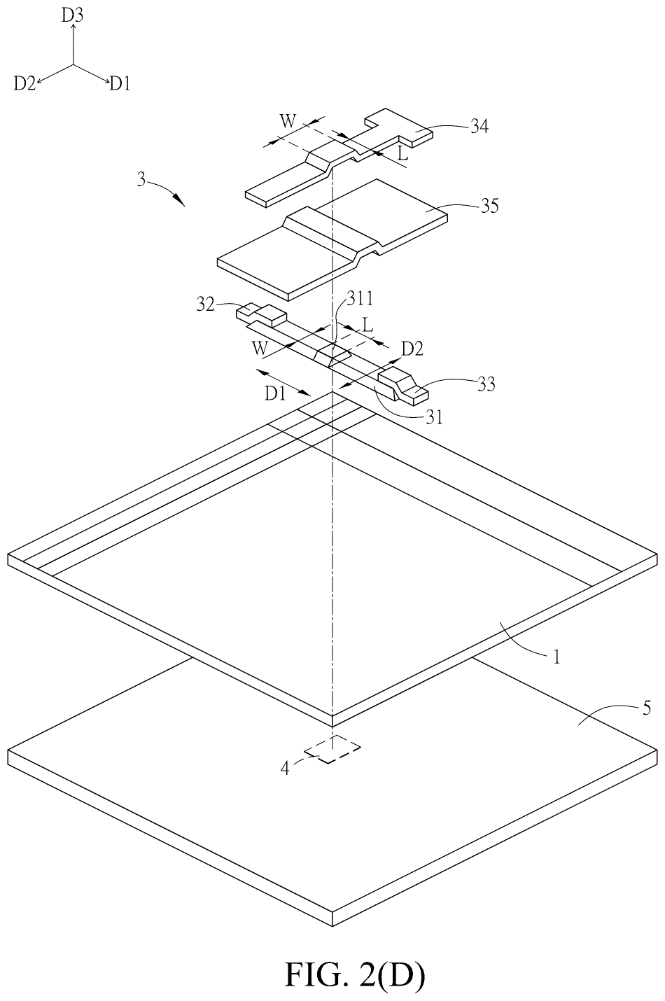

In FIG. 2(A), the electronic device of this disclosure is further provided with a support board 5 stacked under the flexible substrate 1. The guarding portion 4 can be disposed between the flexible substrate 1 and the support board 5 as in FIG. 2(B) or below the support board 5 as in FIG. 2(C). The material of the support board 5 are not limited, and the support board 5 can be made of or include resilient material.

In FIG. 2(B), the guarding portion 4 can be arranged either in or on a top surface of the support board 5, or arranged either in or on a bottom surface of the flexible substrate 1. In FIG. 2(C), the guarding portion 4 can be arranged either in or on a bottom surface of the support board 5. In addition, the guarding portion 4 can also be a part of the support board 5 as shown in FIG. 2(D).

The transistors 3 of the present disclosure can be thin film transistors. In addition, the configurations of the transistors 3 are not limited. In the embodiments of FIG. 1 to FIG. 3, the transistors 3 are top-gate transistors with a current direction from the source electrode 32 to the drain electrode 33. The transistors 3 can also be bottom-gate transistors, double-gate transistors, or the like in some embodiments. The transistors 3 can also be triple-gate transistors, or the like in some embodiments. In these cases, the gated channel 311 of the channel portion 31 is overlaps with the corresponding guarding portion 4 in the projection direction D3 perpendicular to the flexible substrate 1.

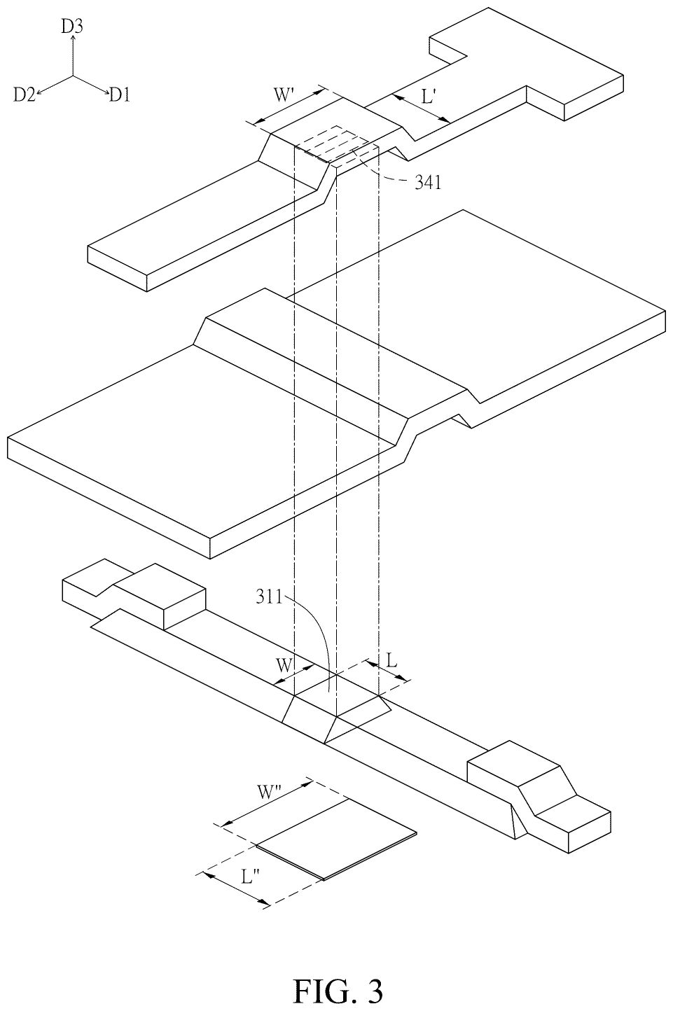

Referring to FIG. 3, the gated channel 311 of the channel portion 31 defines a width W and a length L, and a corresponding region 341 of the gate electrode 34 is defined by the perpendicular projection of the channel portion 311 in the projection direction D3. The corresponding region 341 has a width W′ equals to the width W of the channel portion 311, and a length L′ equals to the length L of the channel portion 311. In FIG. 3, the guarding portion 4 has a similar contour with the gated channel 311 and the correspond region 341 of the gate electrode 34. A width W″ of the guarding portion 4 is no less than the width W of the gated channel 311 and the width W′ of the corresponding region 341, and a length L″ of the guarding portion 4 is also no less than the length L of the gated channel 311 and the length L′ of the corresponding region 341. It means that the length L″ of the guarding portion 4 is longer or the same as the length L of the gated channel 311 or the length L′ of the corresponding region 341, and the width W″ of the guarding portion 4 is longer or the same as the width W of the gated channel 311 or the width W′ of the corresponding region 341.

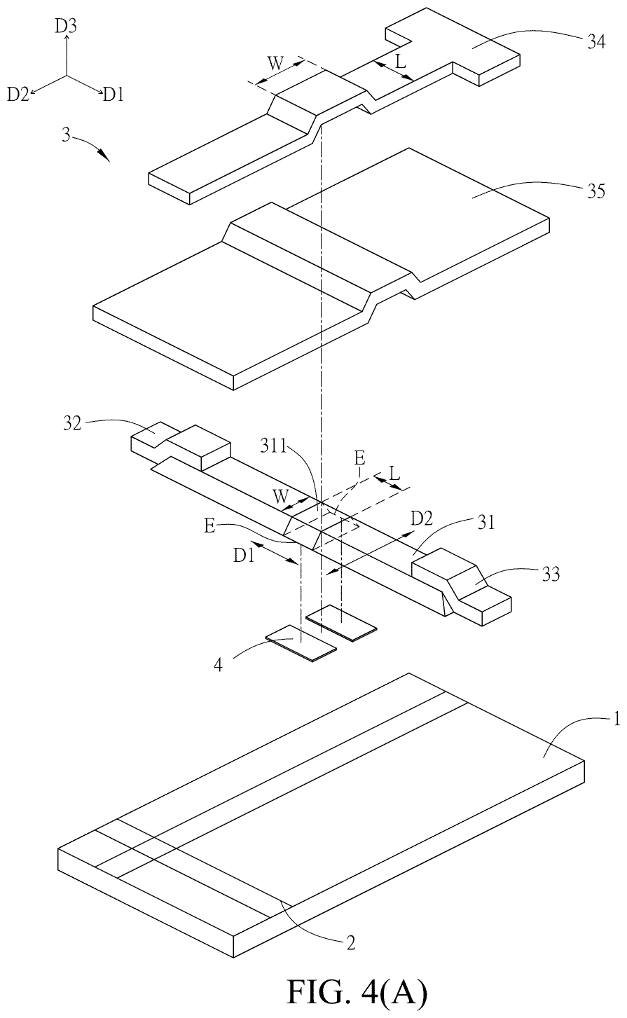

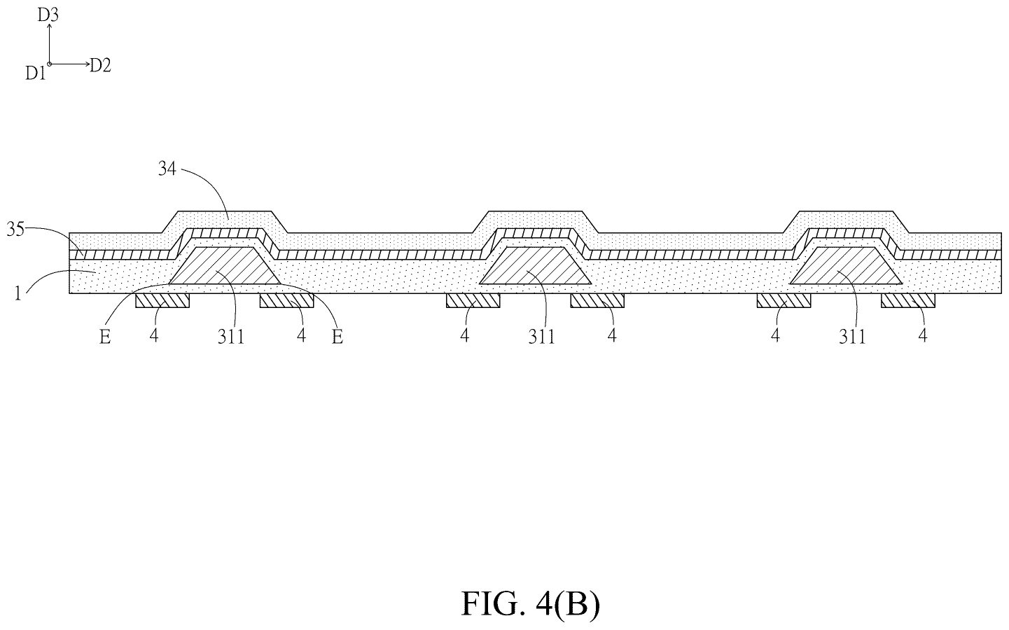

In one case shown by FIG. 4(A) and FIG. 4(B), the two edges E of one gated channel 311 are respectively overlap with two guarding portions 4 in the projection direction D3 perpendicular to the flexible substrate 1.

It is to be noted that without a guarding portion, the transistor(s) on a flexible substrate will be damaged or malfunction after the flexible substrate is bent or rolled. A stress will accumulate at the edge of the gated channel of a transistor when the flexible substrate is bent or rolled, and a damage of the transistor will be caused by the accumulated stress. At last, a current leakage will happen at the edge of the gated channel of the damaged transistor which leads to malfunction of the transistor.

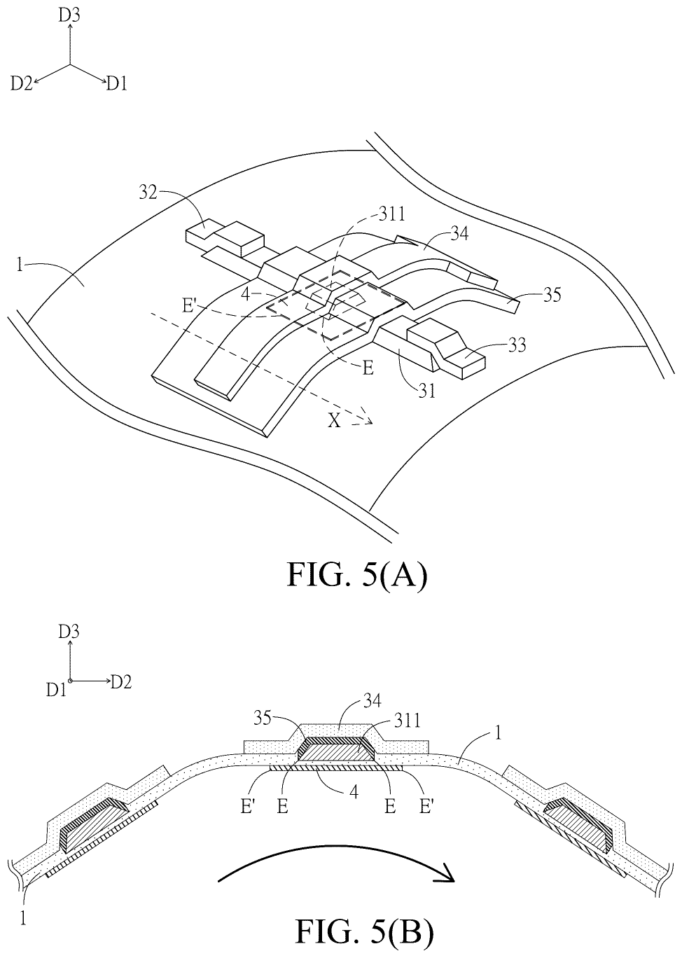

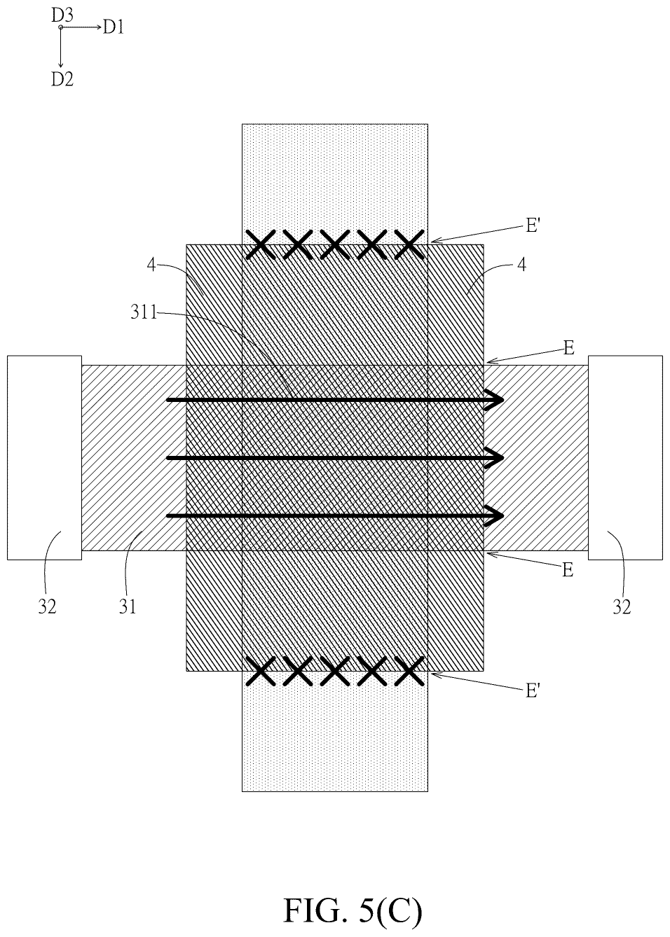

However, when the flexible substrate of the present disclosure is bent or rolled up along an axis X parallel to the direction D1 as shown by FIG. 5(A) and FIG. 5(B), a stress will be accumulated at the edge E′ of the guarding portion 4 as shown in FIG. 5(C) instead of accumulating at the edge E of the gated channel 311. So the function of the gated channel 311 of the transistor 3 will not be affected by the stress accumulated at the edge E′ of the guarding portion 4.

In addition, the stress caused by bending or rolling of the flexible substrate 1 still accumulated at the edge E′ of the guarding portion 4 even the outermost contour thereof is the same as the outermost contour of the corresponding gated channel 311 in the projection direction D3. Therefore, the corresponding gated channel 311 of the transistor 3 is still protected by the guarding portion 4.

In one embodiment, the electronic device of this disclosure further comprises one or more lighting members which are individually from each other and disposed directly on the flexible substrate. The lighting members electrically connect to the conductive pattern layer on the flexible substrate and are each driven by a corresponding one of the transistors.

Accordingly, the electronic device of the present disclosure comprises at least one guarding portion corresponding to at least one transistor on the flexible substrate for spreading out the stress caused by bending or rolling of the electronic device of the present disclosure. The stress will be spread out to the edge of the guarding portion from the edge of the channel portion of the transistor. Therefore, the transistor can maintain its normal function when the electronic device of the present disclosure is bent or rolled.

Although the disclosure has been described with reference to specific embodiments, this description is not meant to be construed in a limiting sense.

Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. An electronic device, comprising:
a flexible substrate;
a conductive pattern layer formed on the flexible substrate;
at least one transistor formed on the flexible substrate and electrically connected to the conductive pattern layer; wherein the least one transistors includes an active layer, a source electrode and a drain electrode respectively electrically connected to the active layer, at least one gate electrode, and an insulation layer disposed between the active layer and the gate electrode, wherein the active layer defines a channel portion and the channel portion defines a gated channel which is overlapped with the gate electrode in a projection direction perpendicular to the flexible substrate, and the channel portion defines a first direction which is a direction a current flowing between the drain electrode and the source electrode, and wherein the gated channel defines a plurality of edges coherent to the first direction; and
at least one guarding portion arranged under the at least one transistor, wherein the at least one guarding portion overlaps at least one of the edges of the gated channel in the projection direction perpendicular to the flexible substrate;
wherein a Young's modulus of the flexible substrate is less than a Young's modulus of the guarding portions.

2. The electronic device as claimed in claim 1, wherein the at least one guarding portion is electrically insulated from the conductive pattern layer.

3. The electronic device as claimed in claim 1, wherein the at least one guarding portion is electrically insulated from the at least one transistor.

4. The electronic device as claimed in claim 1, wherein the at least one guarding portion is disposed on the flexible substrate.

5. The electronic device as claimed in claim 1, wherein the at least one guarding portion is arranged under the flexible substrate.

6. The electronic device as claimed in claim 1, wherein the at least one guarding portion is integrated with the flexible substrate.

7. The electronic device as claimed in claim 1, further including a support board stacked under the flexible substrate, wherein a Young's modulus of the support board is less than the Young's modulus of the at least one the guarding portion.

8. The electric device as claimed in claim 7, wherein the at least one guarding portion is disposed either on the flexible substrate or on the support board.

9. The electric device as claimed in claim 7, wherein the at least one guarding portion is integrated with the support board.

10. The electronic device as claimed in claim 1, wherein the at least one transistor is a thin film transistor.

11. The electronic device as claimed in claim 1, wherein the at least one transistor comprises a single-gate transistor or a multi-gate transistor.

12. The electronic device as claimed in claim 11, wherein the multi-gate transistor comprises a double-gate transistor, or a triple-gate transistor.

13. The electronic device as claimed in claim 1, wherein the at least one transistor is a top-gate transistor or a bottom-gate transistor.

14. The electronic device as claimed in claim 1, wherein the channel portion of the at least one transistor further defines a second direction perpendicular to the first direction, and the channel portion defines a width along the second direction in which the width is a fixed-width.

15. The electronic device as claimed in claim 1, wherein an outermost contour of the at least one guarding portion is square, polygon, circle, or ellipse.

16. The electronic device as claimed in claim 1, wherein the at least one guarding portion is a porous structure, a honeycomb-like structure, a mesh, or a grille-like structure.

17. The electronic device as claimed in claim 1, wherein the at least one guarding portion fully overlaps with the gated channel of the channel portion in the projection direction perpendicular to the flexible substrate.

18. The electronic device as claimed in claim 1, comprising a plurality of the transistors and a plurality of the guarding portions, wherein the at least one of the plurality of the guarding portions overlaps with the gated channels of at least two of the transistors in the projection direction perpendicular to the flexible substrate.

19. The electronic device as claimed in claim 1, further including a plurality of lighting members individually from each other and disposed directly on the flexible substrate, and the lighting members are electrically connected to the conductive pattern layer.

20. The electronic device as claimed in claim 19, wherein one or ones of the lighting members are driven by the at least one transistor.
